(19) United States
(12) Patent Application Publication
(10) Pub. No.: US 2009/0167459 A1
(43) Pub. Date: Jul. 2, 2009

(54) DUPLEXER

(76) Inventors: Michael Jakob, Munich (DE); Gholamreza Dadgar Javid, Munich (DE); Maximilian Pitschi, Rottach-Egern (DE); Karl-Christian Wagner, Unterhaching (DE); Juergen Kiwitt, Munich (DE)

Correspondence Address: FISH & RICHARDSON PC, P.O. BOX 1022, MINNEAPOLIS, MN, 55440-1022, US

(21) Appl. No.: 12/161,772

(22) PCT Filed: Jan. 31, 2007
(86) PCT No.: PCT/DE07/00175

§ 371 Date: Aug. 14, 2008

(30) Foreign Application Priority Data
Feb. 6, 2006 (DE) 10 2006 005 298.6

(51) Int. Cl. H03H 9/70; H03H 7/38; H03H 9/72

(52) U.S. Cl. 333/129; 333/133

(57) ABSTRACT

A duplexer is described herein. The duplexer includes a transmission branch configured to allow passage of signals in a transmission band. The duplexer also includes a reception branch configured to allow passage of signals in a reception band. The duplexer also includes a band rejection filter in the transmission branch configured to produce a short circuit to an electrical ground in a stopband. The stopband at least partially overlaps the reception band.

A duplexer is a switch that comprises a transmission filter and a reception filter.

Filters with ladder-type resonators are known, for example, from the publication U.S. Pat. No. 6,747,530 B1. Different shunt arms of the ladder-type arrangement are electrically coupled with one another for the production of poles in the transfer function.

A goal to be attained is the specification of a duplexer with a high isolation in its reception band.

A duplexer is specified with a transmission branch and a reception branch that are connected to a common antenna. The transmission branch allows signals to pass in the transmission band, and the reception branch allows signals to pass in the reception band. A band rejection filter with a stopband is arranged in the transmission branch, which produces a short circuit to ground in the stopband. The reception band lies at least partially in the stopband of the band rejection filter.

By producing a short circuit to ground in the transmission branch in the reception band or in the vicinity of the reception band, it is possible to obtain, on one hand, a high isolation of the duplexer in the reception band, and on the other hand, a high insertion loss of the transmission branch.

The duplexer includes a reception filter in the reception branch having a passband, wherein the reception band is in the passband of the reception filter.

The duplexer and its advantageous embodiments will be explained in more detail below.

A transmission filter, within the passband of which the transmission band lies, is placed in the transmission branch, wherein the transmission filter comprises the band rejection filter. The transmission filter is preferably a bandpass filter, but in principle can also be a low-pass filter.

The transmission filter preferably has an impedance matching element connected between the antenna and the band rejection filter. The impedance matching element is preferably placed in a serial branch—that is, the signal path of the transmission branch. The matching element can be a capacitor or an acoustic resonator.

The filters placed in the duplexer (reception filter, transmission filter) comprise resonators preferably operating with acoustic waves. A ladder-type arrangement of resonators in the individual filter is considered to be particularly advantageous. A ladder-type arrangement comprises shunt arms and at least one serial branch, which is placed between two successive shunt arms. At least one resonator is placed in each serial branch and shunt arm. The shunt arms connect the signal path with ground.

The signal path always connects two signal-carrying connections. One signal path (transmission path) is connected between the antenna connection and the signal-carrying connection of the transmission branch, and another signal path (reception path) is connected between the antenna connection and the signal-carrying connection of the reception branch.

The transmission filter preferably has at least two shunt arms, which branch off from the transmission path at various electric nodes and are both connected to a common inductor to ground.

The band rejection filter with the coupled shunt arms of a ladder-type arrangement has the advantage that it can be implemented in a transmission filter with only a few basic elements. The use of a limited number of basic elements has the advantage that only relatively few losses arise, so that a low insertion loss of the transmission branch can be obtained, in particular in the transmission band.

A pole in the transfer function of the transmission filter can also be obtained by measures which are described in the publication U.S. Pat. No. 6,747,530 B1. The band rejection filter can also be formed, in principle, by a single shunt arm which has a series resonant circuit. A short circuit to ground is then obtained at the resonance frequency of the series resonant circuit.

A phase shifter, which implements a phase shift of 180° in the Smith diagram at a transmission frequency, is preferably placed between the antenna and the reception filter. This can be, for example, a λ/4 transformer, wherein λ is the electrical wavelength at the transmission frequency.

The duplexer is explained in more detail below with the aid of examples and the pertinent figures. The following are shown schematically:

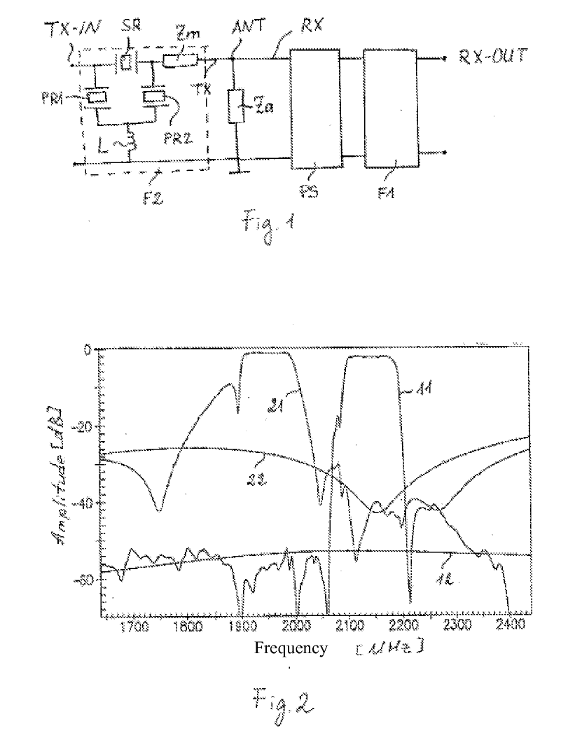

FIG. 1, equivalent circuit diagram of a duplexer with a band rejection filter in the transmission branch, which produces a short circuit to ground in the reception band;

FIG. 2, transfer functions of the sub-circuits of the duplexer.

FIG. 1 shows an equivalent circuit diagram of a duplexer with a transmission path TX and a reception path RX; the two are connected to a common antenna connection ANT. The antenna of the duplexer, which can be connected to the antenna connection ANT, is characterized by an antenna impedance Za.

The reception path RX is arranged between the antenna connection ANT and the reception output RX-OUT. The transmission path TX is arranged between the antenna connection ANT and the transmission input TX-IN. A reception filter F1 is placed in the reception path RX, and a transmission filter F2 is placed in the transmission path TX. A phase shifter PS is placed between the antenna connection ANT and the reception filter F1.

Both filters F1, F2 preferably contain resonators operating with surface acoustic waves or bulk acoustic waves. In FIG. 1, these are resonators placed in various shunt arms of the transmission branch, which are designated as parallel resonators PR1, PR2, and a resonator placed in the serial branch of the transmission path TX, which is designated as serial resonator SR. In principle, several serial resonators and more than two shunt arms with at least one parallel resonator can also be provided in filters F1 and/or F2. At least one serial resonator is provided between two shunt arms. The arrangement of parallel resonators and serial resonators is designated as a ladder-type arrangement.

The transmission filter F2 also comprises an impedance matching element Zm, which is placed in a serial branch between the antenna connection ANT and the ladder-type arrangement of resonators PR1, PR2, SR. The impedance matching element Zm can be a capacitor or a resonator, the resonance frequency of which is preferably outside the bandwidth of the transmission branch and the reception branch, so that in particular in the reception band, essentially only the static capacitor and the resonator provided as the impedance matching element Zm are essential.

The parallel resonators PR1, PR2 are both connected to a common inductance L, which is connected to ground. At a frequency which is preferably in the reception band, the connection of the resonators SR, PR1, PR2, and the inductance L, all together, acts as an effective series resonant circuit which is placed in a shunt arm. This series resonant circuit, which is formed by the inductance L and the static capacitances of the resonators SR, PR1, PR2, creates, at a resonance frequency, a short circuit to ground and therefore acts as a band rejection filter.

The short circuit is preferably transformed into an open circuit at the serial resonance of the band rejection filter by means of the impedance matching element Zm on the antenna-side output of the transmission branch, so that the signal at the output of the transmission branch is almost completely reflected and thus is conducted into the reception branch. In the specified duplexer, the impedances of the band rejection filter, the impedance matching element Zm, and the phase shifter PS are coordinated with one another such that the reception signal can be conducted into the reception path. A relatively low insertion loss in the reception branch can thus be obtained in the reception band.

A relatively low insertion loss in the transmission branch can be obtained in the transmission band if a previously described band rejection filter is used in the antenna-side part of the reception branch. The (other) band rejection filter is then placed in the reception filter. The reception filter preferably also comprises an impedance matching element, placed between the antenna and the band rejection filter, which transforms the short circuit produced in the reception filter into an open circuit at the serial resonance of the band rejection filter. The serial resonance of the band rejection filter is selected such that at least one part of the transmission band overlaps with the stopband of the band rejection filter.

FIG. 2 shows the transfer function 11 of the reception branch and the transfer function 21 of the transmission branch. The transmission band lies between 1900 and 2000 MHz. The reception band lies between 2100 and 2200 MHz.

Moreover, FIG. 2 shows the transfer function 12 of the reception branch, wherein the resonators of the reception filter were replaced by their static capacitance in the calculation. Furthermore, the transfer function 22 of the transmission branch is shown, wherein the resonators of the transmission filter were replaced by their static capacitance. The transfer function 22 has a relatively wide-band pole, which is at the frequency 2150 MHz—that is, in the reception band. It would also be possible to select the pole outside, but in the vicinity of the reception band, so that at least one part of the reception band would lie in the stopband of the band rejection filter.

The design of the duplexer is not limited to the circuitry presented in FIG. 1.

### LIST OF REFERENCE SYMBOLS

ANT Antenna
RX Reception path
TX Transmission path
RX-OUT Reception output
TX-IN Transmission input
F1 Reception filter
F2 Transmission filter
PS Phase shifter
Za Antenna impedance
Zm Impedance matching element
L Inductance
PR1, PR2 Parallel resonators
SR Serial resonator
11 Transfer function of the reception branch
12 Transfer function of the reception branch, wherein the resonators of the reception filter were replaced by their static capacitance
21 Transfer function of the transmission branch
22 Transfer function of the transmission branch, wherein the resonators of the transmission filter were replaced by their static capacitance

1. A duplexer, comprising:
a transmission branch configured to allow passage of signals in a transmission band;
a reception branch configured to allow passage of signals in a reception band; and
a first band rejection filter in the transmission branch configured to produce a short circuit to an electrical ground in a first stopband,
wherein the first stopband at least partially overlaps the reception band.

2. The duplexer of claim 1, further comprising a reception filter in the reception branch having a passband, wherein the reception band is in the passband of the reception filter.

3. The duplexer of claim 1, further comprising a transmission filter in the transmission branch having a passband, the transmission filter including the first band rejection filter, wherein the passband of the transmission filter is in the transmission band.

4. The duplexer of claim 3, wherein the transmission filter includes an impedance matching element electrically connected between an antenna and the first band rejection filter, wherein the antenna electrically connects the transmission branch and the reception branch.

5. The duplexer of claim 4, wherein the impedance matching element comprises a capacitor.

6. The duplexer of claim 4, wherein the impedance matching element comprises an acoustic resonator.

7. The duplexer of claim 1, further comprising resonators operating with acoustic waves.

8. The duplexer of claim 3, wherein the transmission filter comprises at least two shunt arms that are electrically connected to a signal path at different electric nodes and are connected to a common inductor connected to the electrical ground, each of the at least two shunt arms including an acoustic resonator.

9. The duplexer of claim 2, wherein the reception filter comprises:
a second band rejection filter having a second stopband and a serial resonance such that at least a portion of the transmission band overlaps the second stopband, the second band rejection filter producing a short circuit to the electrical around in the second stopband.

10. The duplexer of claim 9, wherein the reception filter comprises an impedance matching element between an antenna and the second band rejection filter, the impedance matching element transforming the short circuit produced in the reception filter into an open circuit at a gate of the antenna at the serial resonance of the second band rejection filter, wherein the antenna connects the transmission branch and the reception branch.
